(19) United States
(12) Patent Application Publication
(10) Pub. No.: US 2012/0292009 A1
(43) Pub. Date: Nov. 22, 2012

(54) Method and Apparatus for Joining Members for Downhole and High Temperature Applications

(75) Inventors: Julian Kähler, Braunschweig (DE); Thomas Kruspe, Wietzendorf (DE); Sebastian Jung, Isernhagen (DE); Gerhard Palm, Sickte (DE); Andrej Stranz, Braunschweig (DE); Andreas Waag, Braunschweig (DE); Erwin Peiner, Braunschweig (DE)

(73) Assignee: BAKER HUGHES INCORPORATED, Houston, TX (US)

(21) Appl. No.: 13/112,047

(22) Filed: May 20, 2011

(51) Int. Cl. E21B 43/00; H01L 23/48

(52) U.S. Cl. 166/65.1; 257/783; 156/325; 257/E23.01; 977/773

(57) ABSTRACT

A method of attaching members is provided. In one aspect, the method includes placing a bonding material comprising at least one of silver micro particles)and silver nano particles on a surface of a first member; placing the first member with the surface of the first member having the bonding material thereon on a surface of a second member; heating the bonding material to a selected temperature while applying a selected pressure on at least one of the first member and second member for a selected time period to sinter the bonding material to attach the first member to the second member.

### BACKGROUND INFORMATION

1. Field of the Disclosure

This disclosure relates generally to devices for use in high temperature environments, including, but not limited to, electronic circuits used in tools made for use in oil and gas wellbores.

2. Brief Description of The Related Art

Electronics components, such as hybrid circuits are commonly used in tools made for use in high temperature environments, such as in deep oil wells, where downhole temperatures can exceed 175° C. A hybrid circuit generally includes a number of integrated circuits and components often referred to as chips or dies attached to a base, also referred to as a substrate. Some of these components also generate heat during their operation. Currently utilized techniques for attaching dies to the substrate are often inadequate for sustained high temperature use. Silver sintering is a technique used for attaching power electronic modules (dies) to substrates. In this process a porous silver layer serves as an adhesive between the die and substrate. A hydraulic press (such as a 50 ton press) is generally used to apply contact pressure of around 40 N/mm². However, this joining technique faces certain drawbacks: (i) the high process pressure poses the risk of cracking or damaging the surface of the joining members; and (ii) the high-load presses used require elaborate handling of the die, such as transistors and sensors dies with small surface areas, such as areas less than 1 mm². Such dies are attached with poor positioning accuracy and poor process capability.

The disclosure herein provides improved apparatus and methods for joining components for use in high temperature and high pressure environments.

### SUMMARY

In one aspect, a method of attaching members is provided. In one aspect, the method includes placing a bonding material comprising a mixture of particles of micrometer size (“micro particles”) and particles of nanometer size (“nano particles”) on a surface of a first member; placing the first member with the surface of the first member having the mixture on a surface of a second member; heating the bonding material to a selected temperature while applying a selected pressure on at least one of the first and second members for a selected time period to sinter the bonding material to attach the first member to the second member.

In another aspect, a device is provided that in one configuration includes a substrate and a die bonded onto the substrate by sintering a bonding material that contains at least one of micro particles and nano particles of a selected material. In one aspect the selected material includes at least one of silver, gold and copper.

Examples of certain features of the apparatus and method disclosed herein are summarized rather broadly in order that the detailed description thereof that follows may be better understood. There are, of course, additional features of the apparatus and method disclosed hereinafter that will form the subject of the claims appended hereto.

### BRIEF DESCRIPTION OF THE DRAWINGS

For detailed understanding of the present disclosure, references should be made to the following detailed description, taken in conjunction with the accompanying drawings in which like elements have generally been designated with like numerals and wherein:

FIG. 1 shows a die for attachment to a substrate using a bonding material comprising silver nano and micro particles;

FIG. 2 shows an exemplary system for attaching a die to a substrate using a bonding material comprising nano and micro silver particles; and

FIG. 3 shows shear strength, porosity and Young's Modulus of bonding between a die attached to a silicone substrate formed according to a method described herein for bonding materials containing 0% to 100% nano silver particles by weight.

### DETAILED DESCRIPTION

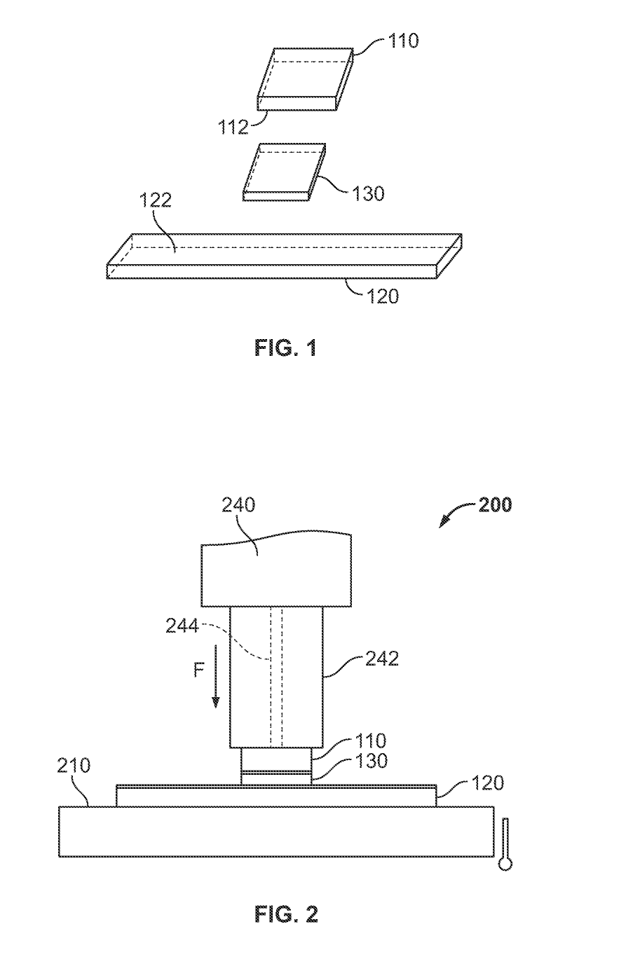

The present disclosure relates to joining or attaching members using a sintered bonding material that includes a mixture of nano particles and micro particles of one or more materials. FIG. 1 shows exemplary members that may be joined or attached to each other according to one embodiment of the disclosure. FIG. 1 shows a member (also referred to as a “die”) 110 that is to be attached to another member (also referred to as a “substrate”) 120 using a bonding material 130. In one aspect, the die 110 may be any suitable member or component, including but not limited to, an electronic component, such as an integrated circuit, transistor, a power component, and an optoelectronic component, such as a light emitting diode, a photo diode or another suitable component. The substrate 120 may be made from any suitable material, including, but not limited to a ceramic material, such as aluminum oxide (Al₂O₃), a metallic material and a semiconducting material (such as silicon, Bi₂Te₃). In one exemplary embodiment, the bonding material 130 is a mixture of nano silver particles and micro silver particles. The bonding material 130 may be in any suitable form, including but not limited to, paste, powder, etc. The nano silver particles and micro silver particles may be of any suitable shape, including, but, not limited to spheres and flakes. To attach the die 110 to the substrate 120, the attaching surface 112 of the die 110 and the attaching surface 122 of the substrate are cleaned. The bonding material 130 is then applied to one of the surfaces 112 and 122. The die 110 is then placed on the substrate 120. A suitable pressure is applied on the die and/or substrate while heating the bonding material 130, such as by heating the substrate and/or die to a suitable temperature for a selected time period to sinter the bonding material 130. The heat is then removed, thereby attaching the die 110 to the substrate 120.

FIG. 2 shows an exemplary apparatus 200 for attaching a die 110 to a substrate 120 using a bonding material 130 comprising a mixture of nano silver particles and micro silver particles. The system 200 of FIG. 2 is shown to include a base plate 210 that may be heated to a temperature sufficient to sinter the selected bonding material and a handling device 240. The sinter temperature of the bonding material is less than the operating temperature of the die and the substrate. The handling device 240, in one embodiment, may include an arm 242 configured to be pressed against the base plate 220 by a suitable mechanism, such as a hydraulically-operated unit, an electrically-operated unit or a pneumatically-operated unit. The system 200 is configured in a manner such that it can apply a relatively precise pressure on the arm 242 and thus also on the base plate 210. In aspects, device 240 may be configured to apply pressure in excess of 40 N/mm². In one configuration, the device 240 includes a vacuum suction mechanism 244 configured to pick a component, such as die 110. An exemplary process of joining the die 110 to a substrate 120 is described below. A surface of one of the die and substrate 120 is coated with the bonding material 130. The substrate 120 is securely placed on the base plate 210. The die is picked up by arm 242 using the vacuum suction 244. The arm 242 may be positioned aided by the use of an optical microscope and an x-y positioning table (not shown) over the base plate 210. The arm 242 is then moved downward till the die 110 with the bonding material 130 contacts the base plate 210. The movement and placement of the joining members 110 and 120 may be observed simultaneously via a suitable vision alignment system (not shown). The joining members 110 and 120 are heated by a heating the base plate 210 to a selected temperature. A contact force “F” is applied to the die 110 and substrate 120 by the arm 242, which force may be varied during the bonding process. In aspects, the contact force F may be applied uniaxially or quasi-hydrostatically. In one aspect, the handling device 242 may be made of silicone and of different hardness. Other suitable materials include stainless steel, temperature-stable and pressure-stable soft plastics, such as polyether ether ketone (PEEK), etc. In aspects, a material with low thermal conductivity is used in order to prevent the cooling of the joining surfaces during the joining process. The use of a soft-contact material, such as silicone, compensates for uneven surfaces. This improves reproducibility and the process capability index (CpK) of the bonding process. The use of silicone also avoids surface damage. The base plate 210 is heated to a desired temperature while applying the selected pressure until the bonding material of silver nano particles and silver micro particles sinters. The temperature is then lowered and pressure on the die 110 relieved. In aspects, the joining process described above may utilize pressure between 0 to 40 MPa at a temperature between 130° C. and 350° C. for a period of 1 minute to 120 minutes. The above-noted process can provide stable die attachment for operations exceeding 350° C.

In one aspect, the sintering process described herein may be utilized for the joining components, such as attaching electronic components on a substrate to form hybrid circuits, which may be achieved by modifying the die attachments mechanism of a commercially available flip-chip bonder, an apparatus used for micro assembly of dies on substrates in the electronic industry. The joining process described herein allows a relatively precise pick-and-place bonding of a die (e.g. transistors, bumped devices for flip-chip die attachment, memory chips, LEDs, sensor, etc.) to an application-specific carrier. This process may also be used for die stacking and three-dimensional (3D) assemblies of electronic components. For example, memory devices and light emitting diodes (LEDs) may be bonded on a Peltier cooler to provide stable operation of such heat-generating devices. Also, the described joining process may be used for the assembly of chip packages on substrates.

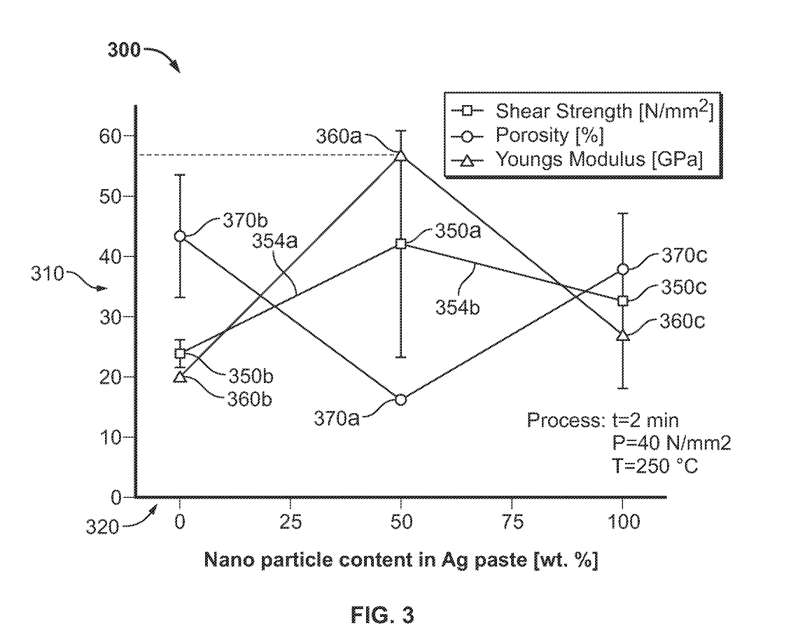

FIG. 3 shows graphs 300 depicting shear strength, porosity and Young's Modulus measured during a laboratory test of an electronic chip (die) bonded onto a silicon substrate according to a method described herein, using a bonding material that contains no silver nano particles (only silver micro particles), 50% by weight silver nano particle and 100% silver nano particles).The vertical scale 310 corresponds to shear force in N/mm², porosity in percentage and Young's Modulus in GPa. The horizontal axis corresponds to the percent of nano sized particles of silver by weight in the bonding material. The dies used for testing were formed by bonding a die on a silicon substrate using an applied pressure of 40 N/mm², the base plate temperature of 250° C. for 2 minutes. FIG. 3 shows that shear strength 350a for the bonding material containing 50% by weight each of the silver nano particles and silver micro particles is about 56 N/mm²; shear strength 350b for a bonding material containing no nano particles (i.e. material containing all silver micro particles) is about 23 N/mm²; and for a bonding material containing all silver nano-particles the shear strength is about 32 N/mm². Extrapolations shown by lines 354a and 354b indicate that the shear strength of components joined by a bonding material containing a mixture of silver nano particles and silver micro components is greater than shear strength obtained by a bonding material containing no silver nano particles. Also, shear strength for 100% nano silver nano particles is greater than shear strength for 100% silver micro particles (32 N/mm² versus 23 N/mm² for the specific case shown in FIG. 3). Shear strength is a measure used to determine suitability of a bonding material for joining electronics components to substrates. Young's modulus, which is the ratio of stress (tensile load) applied to a material and the strain (elongation) exhibited by the material to the applied stress, is another measure of a desired physical property of a material. It is known that higher the Young's Modulus, higher the stiffness. FIG. 3 shows that the Young's Modulus for bonding material containing 50% of silver nano particles and 50% of silver micro particles 360a (55 GPa) is greater than the Young's Modulus 360c (27 GPa) for a bonding material containing 100% silver nano particles, that, in turn is greater than the Young's Modulus 360b (20 GPa) for a bonding material containing 100% silver micro articles. Thus, in the specific casees shown in FIG. 3, the attachment for sintered silver bonding material containing a mixture of silver nano particles and silver micro particles or 100% silver nano particles is stiffer than the bonding material containing 100% micro particles. Additionally, porosity 370a for a bonding material containing about 50%-50% mixture of nano silver particles and micro silver particles (16%) is lower than porosity 370c for 100% nano particles (38%), which is lower than porosity 370b for 100% micro silver particles (43%). FIG. 3 shows that the porosity for a bonding mixture containing nano silver particles and micro silver particles is lower than porosity of a bonding material containing all micro silver particles. In general, the lower the porosity, stronger is the bond. The above test data shows that a mixture of silver nano particles and micro particles is more suitable or desirable bonding material for bonding components using silver sintering. The particular test data shown in FIG. 3 is provided for ease of understanding and is not to be considered as a limitation.

Thus, in one aspect, a method of attaching members is provided. In one aspect, the method includes placing a bonding material comprising a mixture of silver particles of micrometer size (micro particles) and nanometer size (nano particles) on a surface of a first member; placing the first member with the surface of the first member having the mixture on a surface of a second member; heating the bonding material to a selected temperature while applying a selected pressure on at least one of the first and second members for a selected time period to sinter the bonding material to attach the first member to the second member. In one aspect, the silver nano particles in the bonding material are about fifty percent (50%) by weight. I another aspect, the sintering may be accomplished at or above 130° C. and at a pressure of about 40 MPa. In another aspect, the amount of silver nano particles in the bonding material is between 20% and 70% by weight. In another aspect, one of the members may be an electronic component, such as an integrated chip, and the other member a substrate, such as a silicon dioxide plate. The pressure may be applied by a device that places the first member on the second member. In aspects, the sintering time may be greater than one minute. The method may further include picking the first member by a suction device; placing the first member on the second member; and applying the pressure on one of the first member and the second member by applying pressure on the suction device.

In another aspect, the disclosure provides a device that includes a substrate and a die bonded onto the substrate by sintering a bonding material that contains silver micro particles and silver nano particles onto the substrate. In aspects, the bonding material may include silver nano particles between 0% and 100% by weight. The substrate may be made from any suitable material, including silicone dioxide, aluminum, etc. In yet another aspect, the disclosure provides tools for use in wellbores that include circuits containing electronic devices, wherein some such devices include a substrate and a die bonded onto the substrate by sintering a bonding material that contains silver micro particles and silver nano particles.

The foregoing description is directed to particular embodiments for the purpose of illustration and explanation. It will be apparent, however, to persons skilled in the art that many modifications and changes to the embodiments set forth above may be made without departing from the scope and spirit of the concepts and embodiments disclosed herein. It is intended that the following claims be interpreted to embrace all such modifications and changes.

1. A method of attaching members, comprising:
placing a bonding material comprising a at least one of micro particles and nano nano particles on a surface of a first member;
placing the first member with the surface having the bonding material thereon on a surface of a second member;
heating the bonding material to a temperature below the melting point of the bonding material while applying a selected pressure on at least one of the first member and the second member for a selected time period to sinter the bonding material to attach the first member to the second member.

2. The method of claim 1 wherein the bonding material includes about fifty percent silver nano particle by weight.

3. The method of claim 1 wherein the selected temperature is above 130° C.

4. The method of claim 1 wherein the pressure is up to about 40 MPa.

5. The method of claim 1 wherein the bonding material includes between 0% and 100% by weight of silver nano particles.

6. The method of claim 1, wherein the first member is an electronic component and the second member is a substrate.

7. The method of claim 1 further comprising maintaining the pressure on one of the first member and the second member for a period of more than one minute.

8. The method of claim 1 further comprising:
picking the first member by a suction device;
placing the first member on the second member using the suction device; and
applying the pressure on one of the first member and the second member by applying pressure on the suction device.

9. A device, comprising:
a substrate; and
a die bonded onto the substrate by sintering a bonding material that contains at least on of: silver micro particles and silver nano particles.

10. The device of claim 9, wherein the nano particles in the bonding material are about fifty percent (50%) by weight.

11. The device of claim 9, wherein the nano particles in the bonding material are between 0% and 100% by weight.

12. The device of claim 9, wherein the substrate is made from silicone.

13. The device of claim 9, wherein the die is an electronic component.

14. A tool for use in a wellbore, comprising:
an electronic circuit that includes:
a substrate; and
a die bonded onto the substrate by sintering a bonding material that contains micro particles and nano particles.

15. The tool of claim 14, wherein the nano particles in the bonding material are about fifty percent (50%) by weight.

16. The tool of claim 14, wherein the nano particles in the bonding material is between 0% and 100% by weight.

17. The tool of claim 14, wherein the bonding material is selected from a group consisting of: silver, gold and copper.

18. The tool of claim 14, wherein the substrate is made from silicone.

19. A method of attaching a first member to a second member, comprising:
placing a bonding material comprising at least one of micro particles and nano particles between the first member and the second member; and
sintering the bonding material for a selected time period to cause the first member and the second member to attach to each other.

20. The method of claim 19, wherein the bonding material includes nano particles of a material selected from a group consisting of: silver, gold and copper.
